(19) United States
(12) Patent Application Publication
(10) Pub. No.: US 2025/0375934 A1
(43) Pub. Date: Dec. 11, 2025

(54) MOLD, MANUFACTURING METHOD, FILM FORMING METHOD, ARTICLE MANUFACTURING METHOD AND IMPRINT APPARATUS

(71) Applicant: CANON KABUSHIKI KAISHA, Tokyo (JP)

(72) Inventors: TETSUJI OKADA, Saitama (JP); TOSHIKI ITO, Kanagawa (JP)

(21) Appl. No.: 19/226,493

(22) Filed: Jun. 3, 2025

(30) Foreign Application Priority Data
Jun. 7, 2024 (JP) 2024-093205

(51) Int. Cl. B29C 59/02; B29C 59/00; B29L 31/00

(52) U.S. Cl. CPC B29C 59/022; B29C 59/002; B29L 2031/767

(57) ABSTRACT

A mold used in imprint lithography, including a base portion including a mesa portion protruding from a base, an alignment mark which includes a first surface combined to a surface of the mesa portion, and is formed to have a thickness from the first surface to a side opposite to the surface, and a pattern portion including a second surface with a pattern formed thereon and a third surface on an opposite side of the second surface, wherein the pattern portion is formed of an organic material, and the third surface and the surface are combined such that the pattern portion covers the alignment mark.

### BACKGROUND

### Field of the Technology

The present disclosure relates to a mold, a manufacturing method, a film forming method, an article manufacturing method and an imprint apparatus.

### Description of the Related Art

As requirements of miniaturization are increasing for optical members, recording media, semiconductor devices, and MEMS, an imprint technique (optical imprint technique) has received a great deal of attention as a microfabrication technique. In the imprint technique, a curable composition is cured in a state in which a mold with a fine concave-convex pattern formed on the surface is in contact with the curable composition arranged (supplied or applied) onto a substrate. Thus, the pattern of the mold is transferred to the cured film of the curable composition, thereby forming the pattern on the substrate. According to the imprint technique, it is possible to form, on a substrate, a fine pattern (structure) on a several nanometer order.

In order to transfer the pattern of a mold to a curable composition on a substrate with high accuracy using the imprint technique, it is necessary to precisely align the mold and the substrate. In general, the mold and the substrate are aligned by optically detecting an alignment mark provided on the mold and an alignment mark provided on the substrate from the mold side. However, when the mold having a high light transmittance is aligned with the substrate while the mold is in contact with the curable composition, since the difference in refractive index between the mold and the curable composition is small, the alignment mark becomes unclear and it is difficult to perform the alignment.

To solve this problem, Japanese Patent Laid-Open No. 2013-519236 discloses a technique for increasing the contrast of an alignment mark by leaving a high-contrast film only in the concave portion of the alignment mark formed on the surface of a mold.

However, as in the conventional technique, a film provided on the surface of a mold is decreased in thickness during mold cleaning or the like, and this leads to a degradation in the contrast of the alignment mark.

In addition, a complicated process is required to provide a high-contrast film only in the concave portion of the alignment mark. Normally, by repeatedly executing the imprint process, the mold is deteriorated or damaged, and a new mold needs to be manufactured each time. Therefore, if the alignment mark is formed through the complicated process each time the mold is manufactured, the manufacturing cost of the mold increases.

### SUMMARY

The present disclosure provides a new technique concerning a mold which is advantageous in terms of alignment and manufacturing cost.

According to one aspect of the present disclosure, there is provided a mold used in imprint lithography, including a base portion including a mesa portion protruding from a base, an alignment mark which includes a first surface combined to a surface of the mesa portion, and is formed to have a thickness from the first surface to a side opposite to the surface, and a pattern portion including a second surface with a pattern formed thereon and a third surface on an opposite side of the second surface, wherein the pattern portion is formed of an organic material, and the third surface and the surface are combined such that the pattern portion covers the alignment mark.

Features of the present disclosure will become apparent from the following description of embodiments with reference to the attached drawings. The following description of embodiments are described by way of example.

### BRIEF DESCRIPTION OF THE DRAWINGS

FIGS. 1A and 1B are views for describing configurations of a mold according to an aspect of the present disclosure.

FIG. 2 is a view for describing configurations of a mold according to an aspect of the present disclosure.

FIG. 3A is a view for describing a manufacturing method for manufacturing a mold.

FIG. 3B is a view for describing a manufacturing method for manufacturing a mold.

FIG. 3C is a view for describing a manufacturing method for manufacturing a mold.

FIG. 3D is a view for describing a manufacturing method for manufacturing a mold.

FIG. 3E is a view for describing a manufacturing method for manufacturing a mold.

FIG. 3F is a view for describing a manufacturing method for manufacturing a mold.

FIG. 3G is a view for describing a manufacturing method for manufacturing a mold.

FIG. 3H is a view for describing a manufacturing method for manufacturing a mold.

FIG. 4A is a view for describing a film forming method (imprint process).

FIG. 4B is a view for describing the film forming method.

FIG. 4C is a view for describing the film forming method.

FIG. 4D is a view for describing the film forming method.

FIG. 5 is a schematic view illustrating configurations of an imprint apparatus according to an aspect of the present disclosure.

FIGS. 6A to 6F are views for describing an article manufacturing method.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### [Mold]

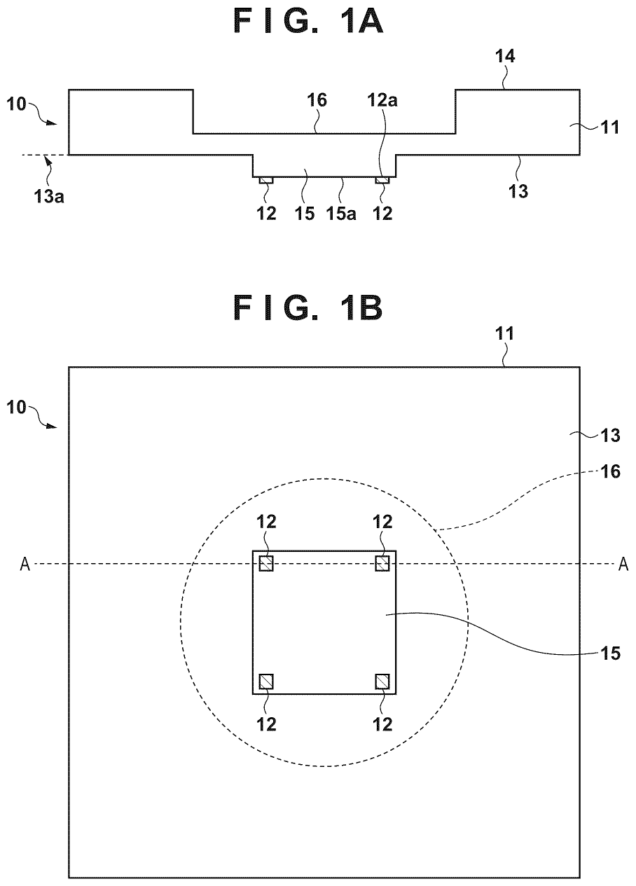

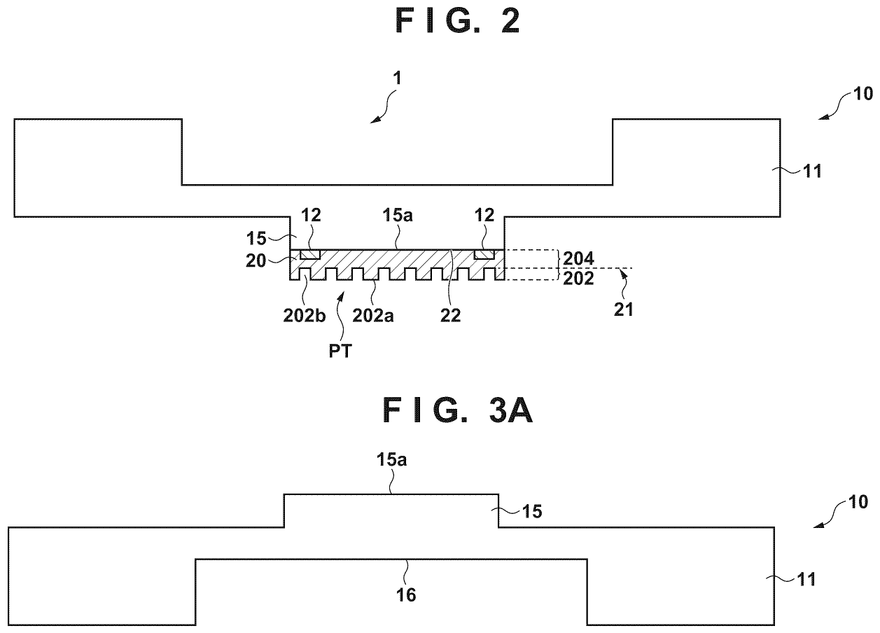

FIGS. 1A to 2 are views for describing configurations of a mold 1 according to an aspect of the present disclosure. The mold 1 is a mold (a mold, a template, or an original) used in imprint lithography (an imprint apparatus employing an imprint technique), and includes, for example, a replica mold manufactured from a master mold. As shown in FIG. 2, the mold 1 includes a reuse portion 10 and a replacement portion 20. FIG. 1A is a sectional view schematically showing the reuse portion 10, and FIG. 1B is a plan view schematically showing the reuse portion 10. Note that FIG. 1A is a sectional view taken along a line A-A shown in FIG. 1B. FIG. 2 is a sectional view schematically showing the mold 1 including the reuse portion 10 and the replacement portion 20.

The reuse portion 10 is a base portion formed by a base 11. The base 11 includes a first base surface 13 and a second base surface 14 on the opposite side of the first base surface 13. On the first base surface 13, a mesa portion 15 is formed that protrudes from a plane 13a to the opposite side of the second base surface 14 to form a convex shape, that is, to form a convex structure (step structure) higher than the periphery. In this manner, the reuse portion 10 includes the mesa portion 15 protruding from the base 11. On the other hand, in the second base surface 14, a concave portion 16 (core out) having a concave shape on the side of the first base surface 13 is formed. As shown in FIGS. 1A and 1B, the concave portion 16 is formed in the second base surface 14 such that a region (a circle indicated by a dotted line) formed by orthogonally projecting the concave portion 16 to the first base surface 13 overlaps the mesa portion 15. Furthermore, the concave portion 16 is formed in the second base surface 14 such that the region formed by orthogonally projecting the concave portion 16 to the first base surface 13 has an area larger than the area of the mesa portion 15. In other words, the mesa portion 15 is located inside the region formed by orthogonally projecting the concave portion 16 to the first base surface 13.

The base 11 is formed of a material that transmits curing light and light for alignment. For example, the base 11 is formed of synthetic quartz, soda glass, calcium fluoride, a resin, or the like. The base 11 is formed of a material (high elastic modulus material) having an elastic modulus of 20 GPa or more, preferably a material having an elastic modulus of 50 GPa or more, and particularly preferably a material having an elastic modulus of 70 GPa or more. The base 11 has a size of, for example, 152.4 mm (6 inches) in length×152.4 mm (6 inches) in width×6.35 mm (0.25 inches) in thickness, but is not limited to this.

Alignment marks 12 are formed on a surface 15a of the mesa portion 15 protruding from the base 11 (outward from the surface layer of the mesa portion 15). The alignment mark 12 includes a combining surface 12a (first surface) combined to the surface 15a of the mesa portion 15, and is formed to have a thickness from the combining surface 12a to a side opposite to the surface 15a of the mesa portion 15. In this embodiment, in the portion where the mesa portion 15 and the alignment mark 12 contact each other, the surface 15a of the mesa portion 15 is a flat surface (flat), and processing to form a concave-convex shape (depression) is not particularly needed.

In this embodiment, the alignment mark 12 is formed by a diffraction grating. The alignment mark 12, that is, a grating pattern forming the diffraction grating is formed of a material, for example, chromium, chromium nitride, tantalum, tungsten, or the like, whose optical property such as a refractive index is different from that of the base 11.

The arrangement of the alignment marks 12 in the in-plane direction of the mesa portion 15 is not particularly limited. However, as shown in FIG. 1B, the alignment marks 12 are preferably arranged in at least four locations (for example, four corners of the mesa portion 15) on the mesa portion 15. From the positions (positional deviations) of the alignment marks 12 arranged in at least four locations on the mesa portion 15, for example, it is possible to decompose an alignment error into a shift component, a rotation component, a magnification component, and a trapezoid component. This makes it easier to correct the alignment error.

FIG. 2 shows a state (mold 1) in which the replacement portion 20 is combined to the reuse portion 10. The replacement portion 20 is a pattern portion that includes a pattern surface 21 (second surface) on which a pattern PT corresponding to a pattern to be transferred to a transfer target is formed, and a surface 22 (third surface) on the opposite side of the pattern surface 21. The replacement portion 20 is combined to the mesa portion 15 so as to cover the alignment marks 12 via the surface 22. In other words, the surface 22 and the surface 15a of the mesa portion 15 are combined such that the replacement portion 20 covers the alignment marks 12 formed on the mesa portion 15.

For the material of the replacement portion 20, an organic material is used. The replacement portion 20 is formed of, for example, a curable composition such as a photocurable composition or a thermosetting composition.

Furthermore, the replacement portion 20 is formed of a material having an elastic modulus lower than the elastic modulus of the base 11 (reuse portion 10). For example, the replacement portion 20 is formed of a material (low elastic modulus material) having an elastic modulus of 10 GPa or less, preferably a material having an elastic modulus of 3 GPa or less, and particularly preferably a material having an elastic modulus of 1 GPa or less.

As shown in FIG. 2, the surface 15a of the mesa portion 15, on which the alignment marks 12 are formed, and the pattern surface 21, on which the pattern PT is formed, are located at different positions in the out-of-plane direction of the pattern surface 21. Therefore, unlike a case in which the alignment mark 12 and the pattern surface 21 are on the same plane, the pattern PT can be formed on the pattern surface 21 even at a position facing the alignment mark 12. In other words, the alignment mark 12 may overlap at least a part of a region formed by orthogonally projecting the region (pattern region) of the pattern PT on the pattern surface 21 to the surface 15a of the mesa portion 15. Furthermore, the alignment mark 12 may be located inside the region formed by orthogonally projecting the region of the pattern PT on the pattern surface 21 to the surface 15a of the mesa portion 15. This can improve the degree of freedom in design of the pattern PT formed on the pattern surface 21.

### [Mold Manufacturing Method]

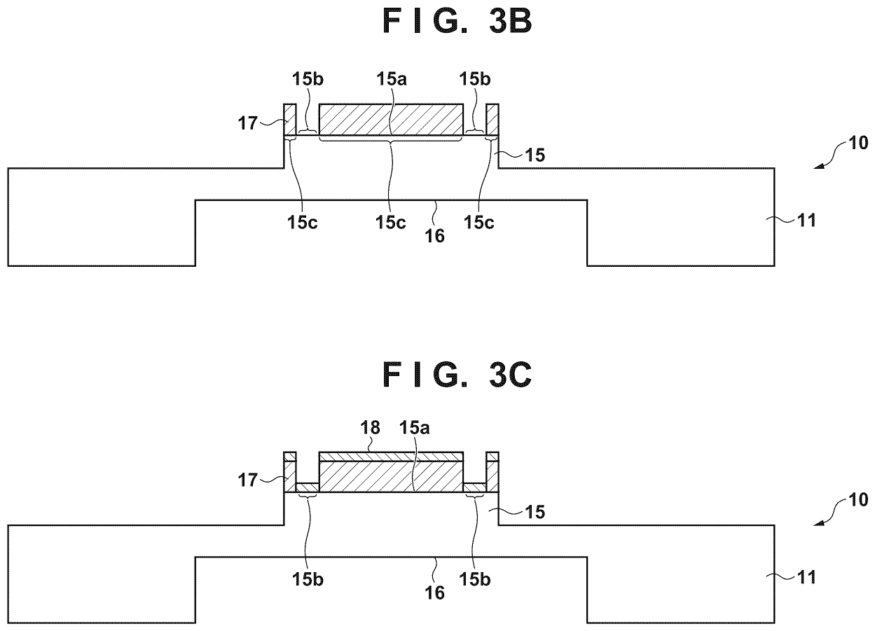

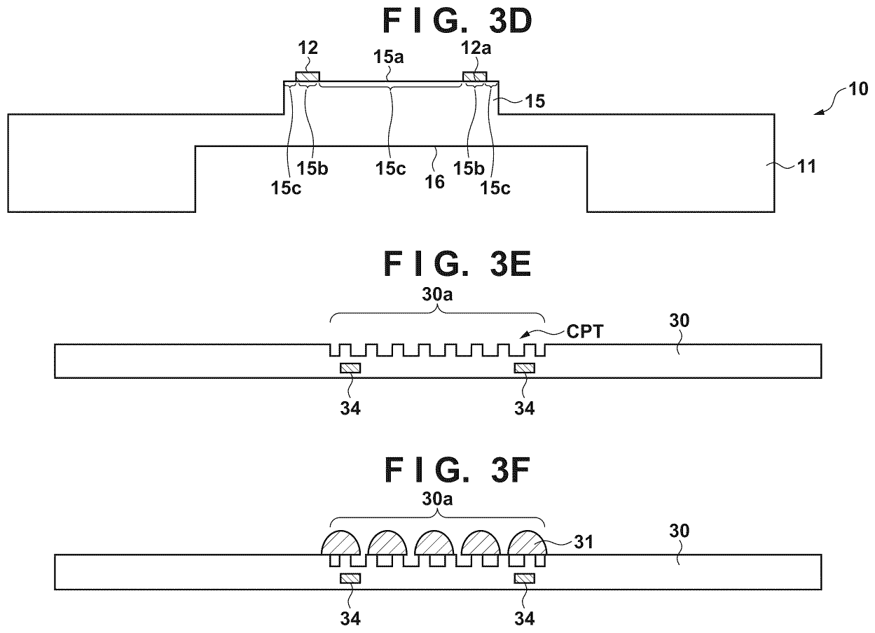

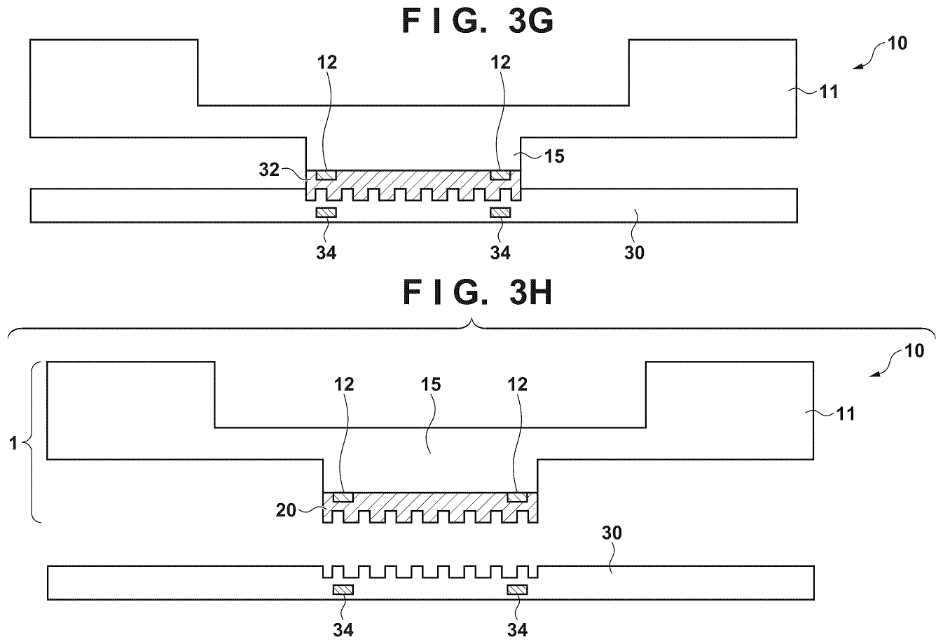

A manufacturing method for manufacturing the mold 1 will be described next. FIGS. 3A to 3H are views for describing a manufacturing method for the mold 1, each of which is a sectional view schematically showing the mold 1 in each manufacturing step.

First, as shown in FIG. 3A, the base 11 is prepared. The base 11 can be manufactured by forming the mesa portion 15 and the concave portion 16 by wet-etching, for example, a rectangular parallelepiped piece of synthetic quartz having a size of 152.4 mm in length×152.4 mm in width×6.35 mm in thickness.

Then, as shown in FIG. 3B, on the surface 15a of the mesa portion 15, a resist film 17 is formed in a non-forming region 15c (a region where the alignment mark 12 is not to be formed) except for a forming region 15b where the alignment mark 12 is to be formed (first step). Note that in a case of forming the alignment mark 12 by a diffraction grating, the resist film 17 is also formed in the region corresponding to the slit portion (the portion where the base 11 is exposed) of the diffraction grating.

Then, as shown in FIG. 3C, a film 18 made of the material for the alignment mark 12 is formed so as to cover the surface 15a of the mesa portion 15, more specifically, the forming region 15b and the resist film 17 (second step). In this embodiment, chromium is used as the material for the alignment mark 12, and a chromium film is formed as the film 18.

Then, as shown in FIG. 3D, by removing the resist film 17 formed in the non-forming region 15c of the surface 15a of the mesa portion 15, the film 18 on the resist film 17 is also removed (lifted off), thereby forming the alignment mark 12 by the film 18 remaining in the forming region 15b (third step). Accordingly, the alignment mark 12 is formed (outward from the surface layer of the mesa portion 15) to have a thickness from the combining surface 12a, which is combined to the surface 15a of the mesa portion 15, to a side opposite to the surface 15a of the mesa portion 15.

Then, as shown in FIG. 3E, a master mold 30 is prepared. The master mold 30 includes, on its surface, a corresponding pattern region 30a where a corresponding pattern CPT corresponding to the pattern PT to be formed on the pattern surface 21 of the replacement portion 20 is formed. The corresponding pattern CPT is formed using, for example, a microfabrication technique such as an electron beam drawing technique. The corresponding pattern CPT is an inverted pattern of the pattern PT. The master mold 30 is formed by, for example, a mold made of a non-light transmitting material or a mold made of a light transmitting material. Examples of the base of the mold made of a non-light transmitting material include a silicon wafer, nickel, copper, stainless steel, titanium, SiC, mica, and the like. Examples of the base of the mold made of a light transmitting material include glass such as silica glass, polydimethylsiloxane, cyclic polyolefin, polycarbonate, polyethylene terephthalate, transparent fluororesin, and the like. Note that the mold made of a light transmitting material may be formed of a plurality of materials.

In order to form the replacement portion 20 on the reuse portion 10 with high positional accuracy, it is necessary to align the reuse portion 10 and the master mold 30 with high accuracy. To achieve such alignment, the master mold 30 is formed with corresponding alignment marks 34 that correspond to the alignment marks 12 formed on the surface 15a of the mesa portion 15. The alignment between the reuse portion 10 and the master mold 30 (replacement portion 20) will be described later in detail.

Then, as shown in FIG. 3F, a curable composition 31 is arranged on the corresponding pattern region 30a of the master mold 30 as the material for the replacement portion 20 (fourth step). The curable composition 31 contains, for example, a polymerizable compound, a photopolymerization initiator, and a solvent. In this embodiment, the curable composition 31 has a viscosity of 2 mPa·s or more and 60 mPa·s or less at 23° C. and 1 atm. The content of the solvent in the whole of the curable composition is more than 5 vol % and 95 vol % or less. The boiling point of the solvent is less than 250° C. at 1 atm. The composition obtained by removing the solvent from the curable composition 31 has a viscosity of 20 mPa·s or more and 10,000 mPa·s or less at 23° C. and 1 atm. In this embodiment, a plurality of droplets of the curable composition 31 are arranged on the corresponding pattern region 30a using an inkjet method. The droplets of the curable composition 31 are densely arranged on a region where concave portions forming the corresponding pattern CPT of the master mold 30 densely exist, and coarsely arranged on a region where concave portions forming the corresponding pattern CPT of the master mold 30 coarsely exist. Hence, a residual film in the cured film of the curable composition 31 formed on the master mold 30 is controlled to have a uniform thickness regardless of whether the corresponding pattern CPT of the master mold 30 is dense or coarse.

Then, as shown in FIG. 3G, the surface 15a of the mesa portion 15 with the alignment marks 12 formed thereon is brought into contact with the droplets of the curable composition 31 on the corresponding pattern region 30a of the master mold 30 (fifth step). Thus, a film 32 of the curable composition 31 is formed between the corresponding pattern region 30a of the master mold 30 and the surface 15a of the mesa portion 15. At this time, the curable composition 31 fills the concave portions of the corresponding pattern CPT of the master mold 30, so that the film 32 is formed into a shape including an inverted pattern (pattern PT) of the corresponding pattern CPT.

When aligning the reuse portion 10 and the master mold 30 with high accuracy (forming the replacement portion 20 on the reuse portion 10 with high positional accuracy), the alignment marks 12 of the mesa portion 15 and the corresponding alignment marks 34 of the master mold 30 are used. In this manner, in this embodiment, after the curable composition 31 and the mesa portion 15 are brought into contact with each other, the reuse portion 10 (mesa portion 15) and the master mold 30 are aligned using the alignment marks 12 and the corresponding alignment marks 34.

Similar to the alignment mark 12, the corresponding alignment mark 34 is formed by a diffraction grating. However, the pitch of the diffraction grating forming the corresponding alignment mark 34 is different from the pitch of the diffraction grating forming the alignment mark 12. When the diffracted light from the diffraction grating forming the corresponding alignment mark 34 and the diffracted light from the diffraction grating forming the alignment mark 12 overlap each other, moire is generated. At this time, since the phase of the moire changes depending on the relative positions of the diffraction gratings, the relative position between the master mold 30 and the reuse portion 10 (mesa portion 15) can be obtained by detecting the moire.

Then, in a state in which the curable composition 31 on the corresponding pattern region 30a of the master mold 30 and the surface 15a of the mesa portion 15 are in contact with each other, the curable composition 31 is cured (sixth step). More specifically, after the alignment between the master mold 30 and the reuse portion 10 (mesa portion 15) in the in-plane direction is completed, the film 32 of the curable composition 31 is cured by irradiating the film 32 of the curable composition 31 with curing light. With this, the mesa portion 15 of the base 11 and the film 32 of the curable composition 31 (replacement portion 20) are combined so as to cover the alignment marks 12.

Then, as shown in FIG. 3H, the master mold 30 is separated from the film 32 of the curable composition 31 (cured curable composition 31), and thus the replacement portion 20 covering the alignment marks 12 is formed on the surface 15a of the mesa portion 15 (seventh step). Note that, in order to increase the adhesion force between the film 32 of the curable composition 31 and the reuse portion 10 to make it easier to separate the master mold 30, it is preferable to previously vapor-deposit an adhesive material on the surface 15a of the mesa portion 15 after the alignment marks 12 are formed.

Through the steps described above, the mold 1 is manufactured, that includes the reuse portion 10 and the replacement portion 20 including the pattern PT as the inverted pattern of the corresponding pattern CPT of the master mold 30. Here, as shown in FIG. 2, the replacement portion 20 includes a portion 202 that includes a convex portion 202a protruding from the pattern surface 21 and defines the pattern PT, and a portion 204 (basal part) between the pattern surface 21 and the surface 22 on the opposite side of the pattern surface 21. The portion 204 is the film 32 of the curable composition 31 remaining between a concave portion 202b and the pattern surface 21, that define the pattern PT, and the surface 22 on the opposite side of the pattern surface 21. The portion 204 is called a residual film.

The thickness of the portion 204 (residual film) defined by the distance between the pattern surface 21 and the surface 22 on the opposite side of the pattern surface 21 is not particularly limited, but needs to be larger than the thickness of the alignment mark 12 to cover the alignment mark 12. As will be described later, the alignment mark 12 is decreased in thickness during replacement of the replacement portion 20, and this causes a degradation in contrast. However, the larger the thickness of the alignment mark 12, the more the influence of the film decrease can be reduced. Therefore, the alignment mark 12 has a thickness of 10 nm or more, and preferably has a thickness of 100 nm or more. In order to cover the alignment mark 12 having such a thickness, the residual film, which is the portion 204 of the replacement portion 20, preferably has a thickness of 100 nm or more.

In this embodiment, the thickness of the alignment mark 12 is set to, for example, 1 μm, which is equal to the width (line width) between the slits (between the grating patterns) of the diffraction grating forming the alignment mark 12. If the alignment mark 12 has a thickness of 1 μm, the influence of the film decrease during replacement of the replacement portion 20 can be made sufficiently insignificant.

### [Film Forming Method]

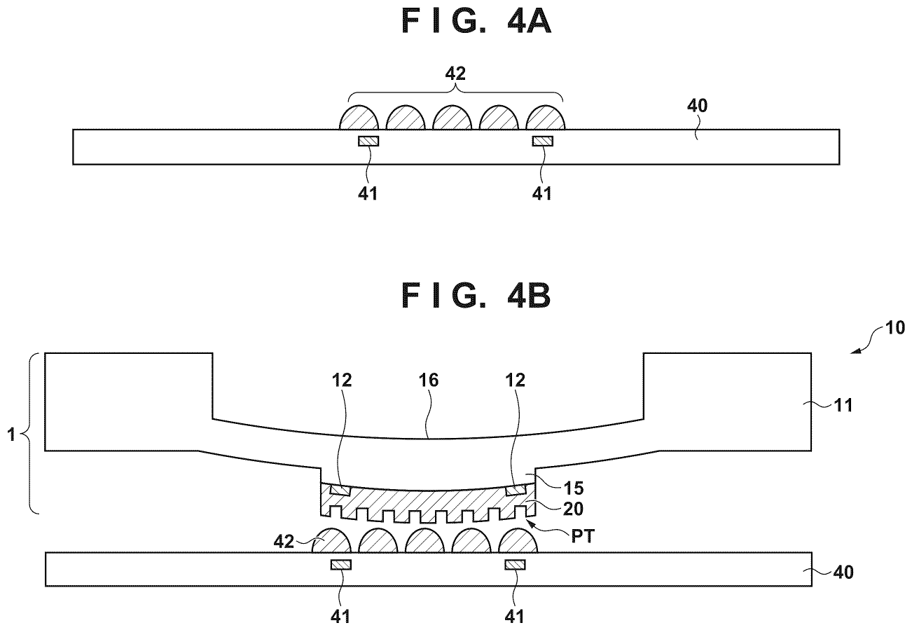

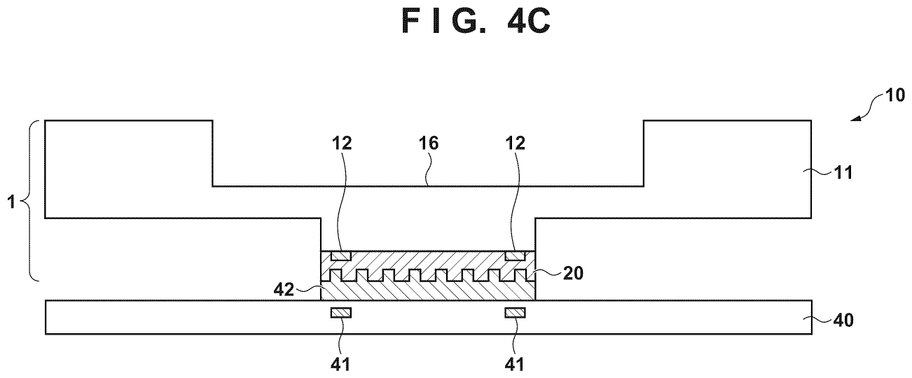

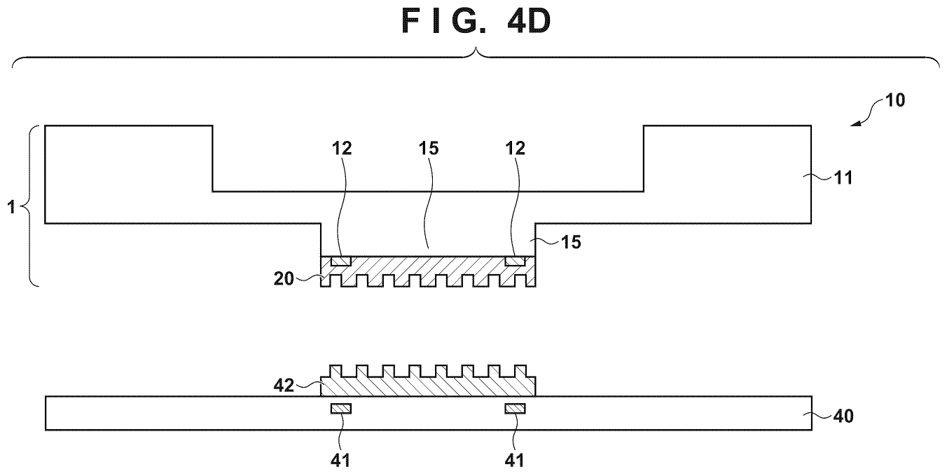

Next, a film forming method using the mold 1 will be described. This film forming method forms a pattern on a substrate by forming a film of a curable composition in a space between the mold 1 and the substrate. In this embodiment, the film forming method is executed as an imprint process (imprint method) using the mold 1. The substrate includes, for example, a substrate for a semiconductor device, a liquid crystal device, a MEMS, or the like. FIGS. 4A to 4D are views for describing the imprint process as the film forming method, and schematically show respective steps of the imprint process.

First, as shown in FIG. 4A, a curable composition 42 (droplets thereof) for device imprint is arranged on a substrate 40 by an inkjet method (arrangement step). In a step before this step, alignment marks 41 corresponding to the alignment marks 12 formed on the surface 15a of the mesa portion 15 are formed on the substrate 40. Similar to the alignment mark 12, the alignment mark 41 is formed by a diffraction grating. However, the pitch of the diffraction grating forming the alignment mark 41 is different from the pitch of the diffraction grating forming the alignment mark 12. When the diffracted light from the diffraction grating forming the alignment mark 41 and the diffracted light from the diffraction grating forming the alignment mark 12 overlap each other, moire is generated. At this time, since the phase of the moire changes depending on the relative positions of the diffraction gratings, the relative position between the substrate 40 and the mesa portion 15 (mold 1) can be obtained by detecting the moire.

Then, as shown in FIG. 4B, the mold 1 and the curable composition 42 on the substrate are brought into contact with each other (contact step). In this embodiment, by applying a pressure to the concave portion 16 of the mold 1 while the mold 1 faces the substrate 40, the mesa portion 15 is bent (deformed) and brought into contact with the curable composition 42 on the substrate from the central portion of the pattern PT of the replacement portion 20. Then, by releasing the pressure in the concave portion 16 of the mold 1 to the atmospheric pressure, the pattern PT of the replacement portion 20 gradually comes into contact with the curable composition 42 from the central portion toward the outer peripheral portion. Finally, as shown in FIG. 4C, the curable composition 42 on the substrate spreads over the entire region of the pattern PT of the replacement portion 20. With this, it can be suppressed that a gas remains between the pattern PT of the replacement portion 20 (mold 1) and the curable composition 42 on the substrate.

Then, after the mold 1 is brought into contact with the curable composition 42 on the substrate, the mold 1 and the substrate 40 are aligned using the alignment mark 12 and the alignment mark 41 (alignment step). More specifically, the moire generated by the alignment mark 12 and the alignment mark 41 is detected, and an alignment error (positional deviation) between the mold 1 (the pattern PT of the replacement portion 20) and the substrate 40 is obtained. Then, the mold 1 and the substrate 40 are aligned so as to reduce the alignment error.

Then, in a state in which the mold 1 and the curable composition 42 on the substrate are in contact with each other and the alignment error is reduced, the curable composition 42 is irradiated with light to cure the curable composition 42 (curing step). Thus, the pattern PT of the replacement portion 20 (mold 1) is transferred to a proper position on the substrate.

Then, as shown in FIG. 4D, the mold 1 is separated from the cured curable composition 42 on the substrate (mold separation step). Thus, a film of the curable composition 42 (a pattern of the curable composition 42) including an inverted pattern of the pattern PT of the replacement portion 20 (mold 1) is formed on the substrate.

### [Replacing Method of Replacement Portion]

By repeatedly executing the imprint process using the mold 1 to manufacture articles such as semiconductor devices, the pattern PT of the replacement portion 20 can be deteriorated or damaged.

In this embodiment, if the pattern PT of the replacement portion 20 is deteriorated or damaged, first, the replacement portion 20 formed on the surface 15a of the mesa portion 15 is peeled off from the surface 15a of the mesa portion 15 (eighth step). When peeling off the replacement portion 20 from the surface 15a of the mesa portion 15, the replacement portion 20 made of an organic material may be dissolved using, for example, a solvent such as a mixture of H₂SO₄ (sulfuric acid) and H₂O₂ (hydrogen peroxide). Note that, as described above, since the alignment mark 12 formed on the surface 15a of the mesa portion 15 is decreased in thickness during replacement of the replacement portion 20 and this causes a degradation in contrast, the alignment mark 12 preferably has a large thickness.

Then, after the replacement portion 20 is peeled off from the surface 15a of the mesa portion 15, the new replacement portion 20 is formed on the surface 15a of the mesa portion 15 (reuse portion 10) with the replacement portion 20 peeled off therefrom (ninth step). To form the new replacement portion 20 on the reuse portion 10, the steps shown in FIGS. 3B to 3H are executed. In this case, since the reuse portion 10 is used repeatedly, it is possible to suppress an increase in cost for manufacturing the mold 1, that is, manufacturing cost, thereby manufacturing the mold 1 inexpensively.

### [Imprint Apparatus]

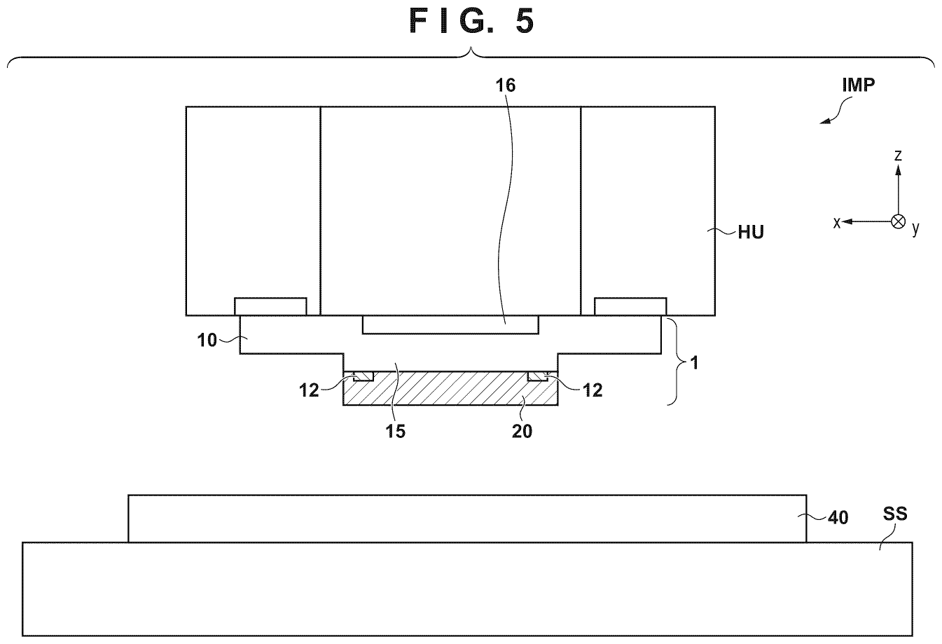

FIG. 5 is a schematic view illustrating configurations of an imprint apparatus IMP according to an aspect of the present disclosure. The imprint apparatus IMP is a lithography apparatus that forms a pattern on a substrate. The imprint apparatus IMP brings a curable composition (imprint material) arranged on a substrate and a mold into contact with each other and applies curing energy to the curable composition, thereby forming a pattern of a cured product to which the pattern of the mold is transferred.

The imprint apparatus IMP includes a holding unit HU that holds the mold 1, and a substrate stage SS that holds the substrate 40. The imprint apparatus IMP also includes a supply unit including a dispenser for arranging (supplying) a curable composition on a substrate, a bridge plate for holding the holding unit HU, a base plate for holding the substrate stage SS, and the like.

The mold 1 is a mold for molding a curable composition on a substrate. As described above, the mold 1 includes the reuse portion 10, and the replacement portion 20 combined to the reuse portion 10 so as to cover the alignment marks 12 formed on the reuse portion 10 (the surface 15a of the mesa portion 15 of the base 11).

The holding unit HU is a holding mechanism for holding the mold 1. The holding unit HU includes, for example, a chuck that vacuum-chucks or electrostatically attracts the mold 1, and a mold driving unit that drives the chuck. The mold driving unit drives (moves) the chuck chucking the mold 1, that is, the mold 1 in the X direction, the Y direction, the Z direction, and the OZ direction.

The substrate stage SS is a holding mechanism for holding the substrate 40 to which the pattern of the mold 1 is transferred. For example, the substrate stage SS vacuum-chucks or electrostatically attracts the substrate 40 via a chuck, and is driven by a substrate driving unit. The substrate driving unit drives the substrate stage SS holding the substrate 40, that is, the substrate 40 in the X direction, the Y direction, the Z direction, and the OZ direction.

In the imprint apparatus IMP, in a state in which the curable composition on the substrate and the mold 1 are in contact with each other, curing light for curing the curable composition is applied from above the apparatus. With this, the curable composition on the substrate is cured. Thereafter, by separating the mold 1, a cured film (cured product) of the curable composition with the pattern of the mold 1 transferred thereto is formed on the substrate.

The pattern of a cured product formed using the imprint apparatus IMP is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, a SRAM, a flash memory, and a MRAM and semiconductor elements such as an LSI, a CCD, an image sensor, and an FPGA. Examples of the mold are molds for imprint. Examples of the optical element are a quantum dot structure, a sub-wavelength antireflection structure, a light extraction structure such as an LED, a photonic crystal, a wire grid polarizing plate for ultraviolet region, a structural birefringence wavelength plate, a diffraction grating, and a metalens.

The pattern of the cured product is directly used as the constituent member of at least some of the above-described articles or used temporarily as a resist mask. After etching or ion implantation is performed in the substrate processing step, the resist mask is removed.

### [Article Manufacturing Method]

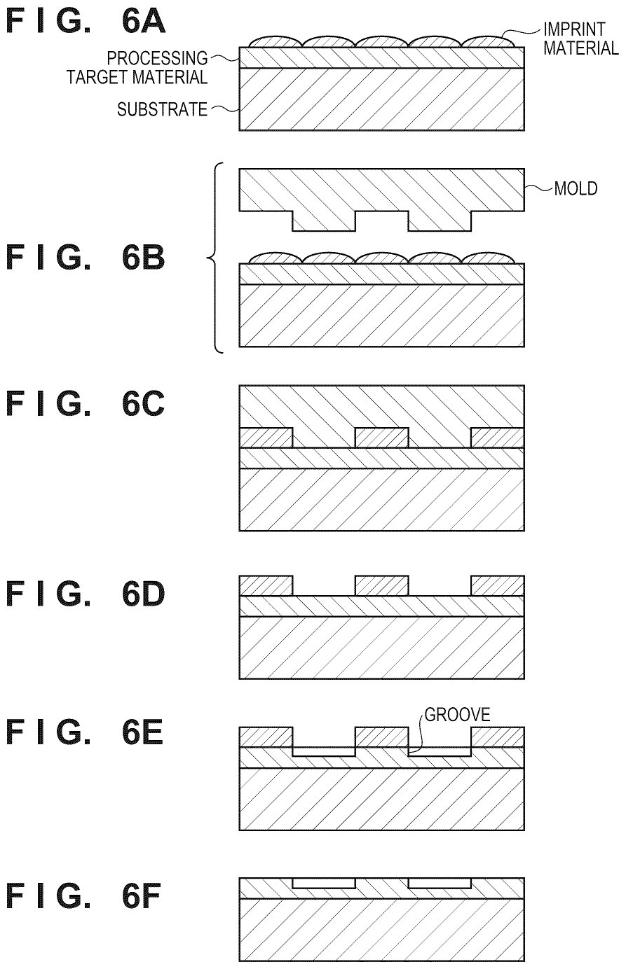

Description regarding a detailed method of manufacturing an article is given. As illustrated in FIG. 6A, the substrate such as a silicon wafer with a processed material such as an insulator formed on the surface is prepared. Next, a curable composition is applied to the surface of the processed material by an inkjet method or the like. A state in which the curable composition is applied as a plurality of droplets onto the substrate is shown here.

As shown in FIG. 6B, a side of the mold with a projection and groove pattern is formed on and caused to face the curable composition on the substrate. As illustrated in FIG. 6C, the substrate to which the curable composition is applied is brought into contact with the mold, and a pressure is applied. The gap between the mold and the processed material is filled with the curable composition. In this state, when the curable composition is irradiated with light serving as curing energy through the mold, the curable composition is cured.

As shown in FIG. 6D, after the curable composition is cured, the mold is released from the substrate. Thus, the pattern of the cured product of the curable composition is formed on the substrate. In the pattern of the cured product, the groove of the mold corresponds to the projection of the cured product, and the projection of the mold corresponds to the groove of the cured product. That is, the projection and groove pattern of the mold is transferred to the curable composition.

As shown in FIG. 6E, when etching is performed using the pattern of the cured product as an etching resistant mask, a portion of the surface of the processed material where the cured product does not exist or remains thin is removed to form a groove. As shown in FIG. 6F, when the pattern of the cured product is removed, an article with the grooves formed in the surface of the processed material can be obtained. The pattern of the cured material is removed here, but, for example, the pattern may be used as a film for insulation between layers included in a semiconductor element or the like without being removed after processing, in other words as a constituent member of the article.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent application No. 2024-093205 filed on Jun. 7, 2024, which is hereby incorporated by reference herein in its entirety.

What is claimed is:

1. A mold used in imprint lithography, comprising:
a base portion including a mesa portion protruding from a base;
an alignment mark which includes a first surface combined to a surface of the mesa portion, and is formed to have a thickness from the first surface to a side opposite to the surface; and
a pattern portion including a second surface with a pattern formed thereon and a third surface on an opposite side of the second surface,
wherein
the pattern portion is formed of an organic material, and
the third surface and the surface are combined such that the pattern portion covers the alignment mark.

2. The mold according to claim 1, wherein the pattern portion has an elastic modulus lower than an elastic modulus of the base portion.

3. The mold according to claim 1, wherein
an elastic modulus of the base portion is not less than 20 GPa, and
an elastic modulus of the pattern portion is not more than 10 GPa.

4. The mold according to claim 1, wherein the surface is formed by a flat surface.

5. The mold according to claim 1, wherein the alignment mark has a thickness of not less than 10 nm.

6. The mold according to claim 1, wherein
the alignment mark is formed by a diffraction grating, and
the alignment mark has a thickness equal to a width between slits of the diffraction grating.

7. The mold according to claim 1, wherein
the pattern portion includes a convex portion protruding from the second surface and defines the pattern, and
a thickness of a basal part defined by a distance between the second surface and the third surface is not less than 100 nm.

8. The mold according to claim 1, wherein the alignment mark overlaps at least a part of a region formed by orthogonally projecting a pattern region of the pattern on the second surface to the surface of the mesa portion.

9. The mold according to claim 1, wherein the alignment mark is located inside a region formed by orthogonally projecting a pattern region of the pattern on the second surface to the surface of the mesa portion.

10. A manufacturing method of manufacturing a mold used in imprint lithography, the mold comprising a base portion including a mesa portion protruding from a base, an alignment mark which includes a first surface combined to a surface of the mesa portion, and is formed to have a thickness from the first surface to a side opposite to the surface, and a pattern portion including a second surface with a pattern formed thereon and a third surface on an opposite side of the second surface, the method comprising:
forming, on the surface of the mesa portion, a resist film in a non-forming region except for a forming region where the alignment mark is to be formed;
forming a film formed of a material for the alignment mark so as to cover the forming region and the resist film; and
forming the alignment mark by the film remaining in the forming region by removing the resist film.

11. The method according to claim 10, wherein
the alignment mark is formed by a diffraction grating, and
in the forming the resist film, the resist film is also formed in a region corresponding to a slit portion of the diffraction grating.

12. The method according to claim 10, further comprising:
arranging a curable composition on a corresponding pattern region of a master mold that includes the corresponding pattern region where a corresponding pattern corresponding to the pattern is formed;
bringing the surface of the mesa portion with the alignment mark formed thereon into contact with the curable composition on the corresponding pattern region;
curing the curable composition in a state in which the curable composition on the corresponding pattern region is in contact with the surface of the mesa portion with the alignment mark formed thereon; and
forming, on the surface of the mesa portion, the pattern portion covering the alignment mark by separating the master mold from the cured curable composition.

13. The method according to claim 12, wherein
the master mold includes a corresponding alignment mark corresponding to the alignment mark, and
in the bringing, after the curable composition on the corresponding pattern region and the surface of the mesa portion with the alignment mark formed thereon are brought into contact with each other, the mesa portion and the master mold are aligned using the alignment mark and the corresponding alignment mark.

14. The method according to claim 12, further comprising:
peeling off, from the surface of the mesa portion, the pattern portion formed in the forming the pattern portion; and
forming, on the surface of the mesa portion from which the pattern portion has been peeled off, a new pattern portion by performing the arranging, the bringing, the curing, and the forming the pattern portion.

15. A film forming method of forming a film of a curable composition in a space between the mold and a substrate by using a mold defined in claim 1, the method comprising:
arranging the curable composition on the substrate;
bringing the mold and the curable composition into contact with each other;
curing the curable composition in a state in which the curable composition and the mold are in contact with each other; and
separating the mold from the cured curable composition on the substrate.

16. An article manufacturing method comprising:
forming a film of a curable composition on a substrate using a film forming method defined in claim 15;
processing the substrate on which the film is formed in the forming; and
manufacturing an article from the processed substrate.

17. An imprint apparatus that forms a pattern of a curable composition on a substrate, comprising
a holding unit configured to hold a mold defined in claim 1.
